(19) United States
(12) Patent Application Publication
(10) Pub. No.: US 2010/0319880 A1
(43) Pub. Date: Dec. 23, 2010

(54) HEAT DISSIPATION DEVICE AND MANUFACTURING METHOD THEREOF

(75) Inventors: FANG-XIANG YU, Shenzhen City (CN); MING-KUN CAO, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/541,128

(22) Filed: Aug. 13, 2009

(30) Foreign Application Priority Data
Jun. 23, 2009 (CN) 200910303542.5

(51) Int. Cl. H05K 7/20; F28D 15/04; F28F 7/00; B21D 53/02

(52) U.S. Cl. 165/104.26; 165/104.33; 165/121; 165/185; 29/890.03; 29/890.032

(57) ABSTRACT

A heat dissipation device includes a heat pipe, a base and a heat sink. The heat pipe includes an evaporating section and a condensing section. The evaporating section includes a flat outside surface at one side thereof. The base includes a top surface and an opposite bottom surface. The base defines a groove at the bottom surface thereof. The evaporating section is received in the groove with the flat outside surface spaced a distance from the bottom surface of the base. A solidified soldering layer is formed between the flat outside surface of the evaporating section and the bottom surface of the base. A bottom of the solidified soldering layer is coplanar to the bottom surface of the base. The heat sink is arranged on the top surface of the base with the condensing section of the heat pipe extending therethrough.

### BACKGROUND

1. Technical Field

The disclosure relates to heat dissipation devices for removing heat from electronic components, and particularly to a heat dissipation device incorporating heat pipes therein. The disclosure also relates to a manufacturing method of such a heat dissipation device.

2. Description of Related Art

Computer electronic components such as central processing units (CPUs) generate lots of heat during normal operation. If not properly removed, such heat can adversely affect the operational stability of computers. Solutions must be taken to efficiently remove the heat from the CPUs. Typically, a heat sink is mounted on a CPU to remove heat therefrom, and a fan is often attached to the heat sink for improving heat-dissipating efficiency of the heat sink. The heat sink commonly comprises a base and a plurality of fins arranged on the base.

Nowadays, CPUs and other related computer electronic components are becoming functionally more powerful and more heat is produced consequently, resulting in an increasing need for removing the heat away more rapidly. Conventional heat sinks made of metal materials, even a fan is used, gradually cannot satisfy the need of heat dissipation. Accordingly, a heat dissipating device incorporating with heat pipes has been designed to meet the current heat dissipation need, as the heat pipe possesses an extraordinary heat transfer capacity and can quickly transfer heat from one point to another thereof. When used, the base defines a groove on a top surface for receiving the one end of the heat pipe therein, a bottom surface of the base contacts the electronic component, and the other end of the heat pipe is connected to the fins. Thus the heat generated by the electronic component is conducted to the base and then transferred to the fins via the heat pipe for further dissipating to ambient air.

However, since the heat generated by the electronic component is firstly conducted to the base and then from the base to the heat pipe, a big thermal resistance is formed between the electronic component and the heat pipe. Moreover, due to a machining tolerance, an unavoidable flatness error is produced between an outer surface of the heat pipe and an inner surface of base around the groove. Thus a contact between the heat pipe and the base is not perfect, and an air clearance which greatly reduces a heat transfer from the base to the heat pipe may be formed. Accordingly, an amount of the heat conducted from the base to the heat pipe at per unit of time is greatly reduced. Heat dissipation efficiency of the heat dissipation device will thereby be further decreased.

It is thus desirable to provide a heat dissipation device which can overcome the described limitations.

### BRIEF DESCRIPTION OF THE DRAWINGS

FIG. 1 is an isometric, exploded view of a heat dissipation device according to an embodiment.

FIG. 2 is similar to FIG. 1, but viewed from a bottom aspect.

FIG. 3 is an isometric, assembled view of the heat dissipation device of FIG. 2.

### DETAILED DESCRIPTION

Reference will now be made to the drawing figures to describe the present heat dissipation device in detail.

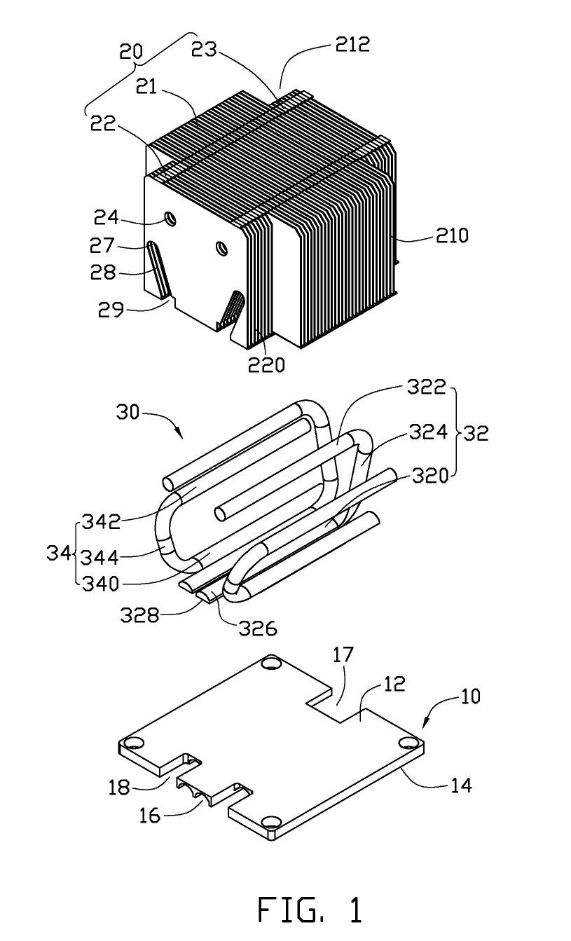

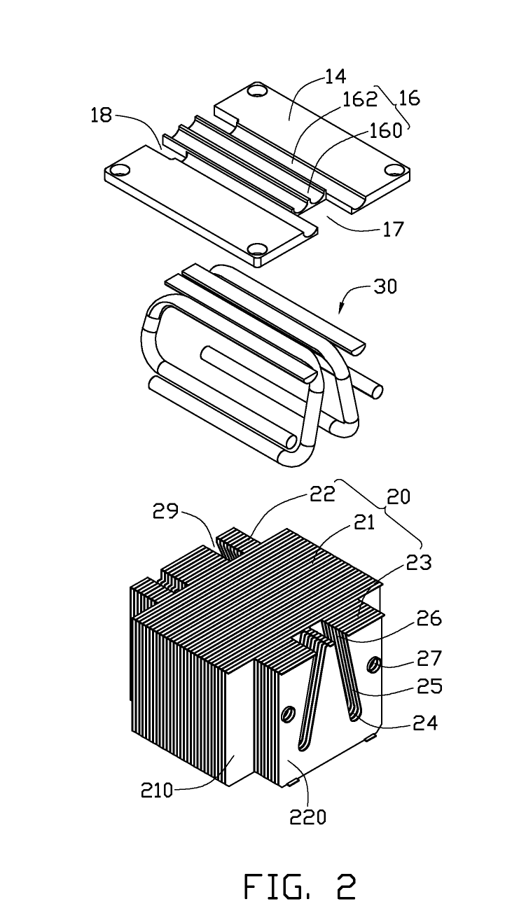

FIGS. 1-2 illustrate a heat dissipation device in accordance with a first embodiment of the disclosure. The heat dissipation device includes a base 10 thermally connecting with electronic component(s) (not shown) for absorbing heat therefrom, a heat sink 20 mounted on the base 10 and a heat pipe unit 30.

The heat pipe unit 30 includes two first heat pipes 32 located at a middle portion thereof and two second heat pipes 34 located at two opposite sides of the first heat pipes 32, respectively. Each of the heat pipes 32, 34 is “U” shaped, and includes an evaporating section 320, 340, a condensing section 322, 342 spaced from and parallel to the evaporating section 320, 340, and an adiabatic section 324, 344 connecting the evaporating section 320, 340 with the condensing section 322, 342. A length of the adiabatic section 324 of each of the first heat pipes 32 is larger than that of the adiabatic section 344 of each of the second heat pipes 34. Thus the condensing section 322 of the first heat pipe 32 is higher than the condensing section 324 of the second heat pipe 34. The evaporating section 320, 340 has across section being substantially semi-circular. The evaporating section 320, 340 includes a flat bottom surface 328 at a bottom side thereof and an arced top surface 326 at a top side. Each of the condensing sections 322, 342 and the adiabatic sections 324, 344 has a circular cross section. A diameter of the condensing sections 322, 342 substantially equals to that of the evaporating section 320, 340.

The base 10 has a top surface 12 and a bottom surface 14 opposite to the top surface 12. The top surface 12 of the base 10 is planar for supporting the heat sink 20 thereon. The base 10 defines four linear grooves 16 in the bottom surface 14 for receiving the evaporating sections 320, 340 of the heat pipes 32, 34 therein correspondingly. The four linear grooves 16 are arranged side by side, and include two first grooves 160 located at a middle of the bottom surface 14 of the base 10 and two second grooves 162 located at two opposite sides of the first grooves 160. Each of the first and second grooves 160, 162 has a substantially semi-circular cross section with a diameter substantially equaling to that of the cross section of the evaporating section 320, 340. A maximal depth of the grooves 160, 162 is slightly larger than a maximal height of the evaporating sections 320, 340 of the first and second heat pipes 32, 34. One end of the base 10 defines a first cutout 17 at a middle portion thereof and simultaneously in communication with the two first grooves 160 along a lengthwise direction of the first grooves 160. The first cutout 17 has a width substantially equal to a sum of widths of the two first grooves 160. Another end of the base 10 defines two second cutouts 18 at two opposite sides of the first grooves 160 and in communication with the two second grooves 162, respectively, along a lengthwise direction of the second grooves 162. Each of the second cutouts 18 has a width substantially equal to a width of each of the second groove 162. The first cutout 17 and the second cutouts 18 are respectively extended through the top and bottom surfaces 12, 14 of the base 10.

The heat sink 20 includes a rectangular first fin assembly 21, and a second fin assembly 22 and a third fin assembly 23 arranged at two opposite sides (i.e., front and rear sides) of the first fin assembly 21, respectively. The first fin assembly 21 includes a plurality of parallel fins 210 arranged side by side. Each of the second and third fin assemblies 22, 23 includes a plurality of parallel heat dissipation vanes 220 arranged side by side and located on front and rear sides of the fins 210. Each of the heat dissipation vanes 220 has a height equaling to that of the fin 210 and a width in a left-to-right direction smaller than that of the fin 210. In this embodiment, each of the fins 210 and the heat dissipation vanes 220 extends along the left-to-right direction of the heat sink 20. The fins 210 are located on a central portion of the heat sink 20. The heat dissipation vanes 220 on the front and rear sides of the first fin assembly 21 are respectively grouped into an integer unit on a middle of a corresponding side of the first fin assembly 21, thus to form four gaps 212 at four corners of the heat sink 20, respectively.

Two first though holes 24 are defined to extend horizontally through a top portion of the heat sink 20. The two first through holes 24 in the second fin assembly 22 are defined adjacent to left and right sides of the second fin assembly 22, respectively. Each of the first through holes 24 extends through the fins 210 and the heat dissipation vanes 220 along a front-to-rear direction. Each of the first through holes 24 receives the condensing section 322 of a corresponding first heat pipe 32 therein. Two first receiving slots 25 are defined in a middle of the third fin assembly 23. The first receiving slots 25 each communicate with a corresponding first through hole 24, and extend linearly and slant towards each other from the corresponding first through hole 24 to a bottom surface of the third fin assembly 23. A bottom end of each of the first receiving slots 25 extends through the bottom surface of the third fin assembly 23 to define a first opening 26 at the bottom surface of the third fin assembly 23. A distance between the two first receiving slots 25 gradually decreases from the first through holes 24 to the first openings 26. A length of the first receiving slots 25 is substantially equals to a length of the adiabatic sections 324 of the first heat pipes 32. Each of the first openings 26 has a width substantially equals to that of the first grooves 160 of the base 10.

Two second through holes 27 are defined to extend horizontally through a middle portion of the heat sink 20. The second through holes 27 in the third fin assembly 23 are defined adjacent to the left end and the right sides of the third fin assembly 23, respectively. The two second through holes 27 are more closer to the left and right sides of the heat sink 20, respectively, than the first through holes 25. Each of the second through holes 27 extends through the fins 210 and the heat dissipation vanes 220 along the front-to-rear direction, and receives the condensing section 342 of a corresponding second heat pipe 34 therein. Two second receiving slots 28 are defined in left and right sides of the second fin assembly 22, respectively. Each of the second receiving slots 28 has a top end communicating with a corresponding second through hole 27, and extends slant towards each other from the corresponding second through hole 27 to a bottom surface of the second fin assembly 22 to define two second openings 29 thereat. Each of the second openings 29 has a width substantially equals to that of the second grooves 162 of the base 10. A distance between the two second receiving slots 28 gradually decreases from the second through holes 27 to the second openings 29. The distance defined between the second openings 29 substantially equals to the sum of widths of the first grooves 160 of the base 10, i.e., a width between the second cutouts 18 of the base 10.

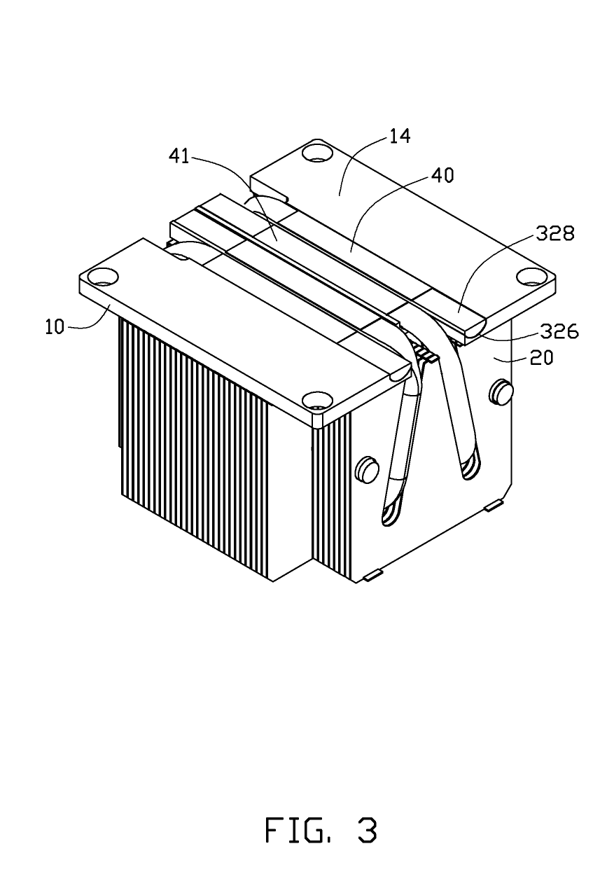

When assembled, the heat sink 20 is mounted on the base 10 with a bottom surface of the heat sink 20 attached to the top surface 12 of the base 10. Referring to FIG. 3 together, the first openings 26 of the first receiving slots 25 are aligned with the first cutout 17, and are respectively in communication with the first grooves 160 via the first cutout 17. The second openings 29 of the second receiving slots 28 are respectively aligned with the second cutouts 18 and in communication with the second grooves 162 via the second cutouts 18. The first through holes 24, the first receiving recesses 25, the first cutout 17 and the first grooves 160 cooperatively form two receiving channels each having a shape corresponding one of the first heat pipes 32; thus, the condensing sections 322 of the first heat pipes 32 can be received in the first through holes 24, the adiabatic sections 324 can be received in the first receiving slots 25 and the evaporating sections 320 can be received in the first grooves 160 to thereby connect the heat sink 20 and the base 10 together. Similarly, the second through holes 27, the second receiving slots 28, the second cutouts 18 and the second grooves 162 cooperatively form another two receiving channels each of which has a shape corresponding to the second heat pipe 34 to receive a corresponding second heat pipe 34 therein. The condensing sections 342 of the second heat pipes 34 can be received in the second through holes 27, the adiabatic sections 344 can be received in the second receiving slots 28 and the evaporating sections 340 can be received in the second grooves 162 to thereby connect the heat sink 20 and the base 10 together.

The arced outside surface 326 of the evaporating sections 320, 340 of the heat pipes 32, 34 contact with inner surfaces of the base 10 around the grooves 160, 162, respectively, while the flat outside surfaces 328 of the evaporating sections 320, 340 are exposed downwardly. Since the maximal depth of the grooves 160, 162 is slightly larger than the maximal height of the evaporating sections 320, 340, the flat outside surfaces 328 is a little higher than the bottom surface 14 of the base 10 whereby a recess is defined between the flat outside surface 328 and the bottom surface 14 of the base 10. Preferably, a difference between the maximal depth of the grooves 160, 162 and the maximal height of the evaporating sections 320, 340 of the heat pipes 32, 34 is varied between 0.1 mm (millimeter) and 0.3 mm, and therefore the distance between the flat outside surface 328 and the bottom surface 14 of the base 10 is varied between 0.1 mm and 0.3 mm.

Due to a machining tolerance, an unavoidable flatness error is produced between the arced outside surfaces 326 and the inner surfaces of base 10 around the grooves 160, 162 to form air clearances therebetween. Thus, a remaining space which is not occupied by the evaporating sections 320, 340 of the heat pipes 32, 34 is defined in each of the grooves 160, 162. Each of the remaining spaces includes the air clearance defined between the arced outside surface 326 and the inner surface of the base 10 around the groove 160, 162 and the recess defined between the flat outside surface 328 and the bottom surface 14 of the base 10. Then, an amount of solder paste is injected into each of the grooves 160, 162 to fill the remaining space. A solidified soldering layer 40 is accordingly formed on each of the flat outside surfaces 328 after the solder paste is solidified, with a part of the solidified soldering layer 40 protruding downwardly beyond the bottom surface 14 of the base 10 due to the manufacturing tolerance. Finally, the protruded part of the solidified soldering layers 40 is milled to from four planar surfaces 41 corresponding to the evaporating sections 320, 340, respectively, which are coplanar to the bottom surface 14 of the base 12. Each of solidified soldering layers 40 has a thickness of about 0.1 mm˜0.3 mm.

When used, the base 12 is thermally conductive relation to the electronic component. The solidified soldering layers 40 and the evaporating sections 322, 340 of the heat pipes cooperatively form a main heat absorbing area at a centre of a bottom surface of the heat dissipation device. The electronic component is directly attached to the planar surfaces 41 of the solidified soldering layers 40. Alternatively, a thermal interface material, for example grease, may be applied between contacting surfaces of the electronic component and the planar surfaces 41 of the solidified soldering layers 40 to increase heat conducting efficiency. Since the solidified soldering layers 40 are milled to form the planar surfaces 41 for perfectly contacting the electronic component, a heat resistance between the heat pipes 30 and the electronic component can be effectively decreased. Thus the heat pipes 32, 34 can quickly absorb heat from the electronic component via the evaporating sections 320, 340 and the solidified soldering layers 40 and then transfer the heat to the top and middle portions of the heat sink 20 via the condensing sections 322, 342. Since the solidified soldering layers 40 can well fill up the air clearances between the heat pipes 32, 34 and the base 10, a lowest thermal resistance between the heat pipe 32, 34 and the base 10 is obtained. Thus the heat pipes 32, 34 can also quickly transfer the heat to a bottom portion of the heat sink 20 via the base 10. The heat on the heat sink 20 is further radiated to ambient air via the fins 210 and the heat dissipation vanes 220 thereof. Thus, the heat dissipation device achieves much better heat dissipation efficiency.

In an alternative embodiment, the solidified soldering layers 40 can be further milled to have a smaller thickness to further decease the heat resistance between the heat pipes 30 and the electronic component, when the electronic component has a width smaller than that of the planar surfaces 41 in combination. In this alternative embodiment, the planar surfaces 41 are located above the bottom surface 14, and the electronic component engages the planar surfaces 41 only when the heat dissipation device is mounted on the electronic component.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device comprising:
at least one heat pipe comprising an evaporating section and a condensing section, the evaporating section comprising a flat outside surface at one side thereof;
a base comprising a top surface and an opposite bottom surface, the base defining at least one groove at the bottom surface thereof, the evaporating section being received in the groove with the flat outside surface spaced a distance from the bottom surface of the base;
a solidified soldering layer formed between the flat outside surface of the evaporating section and the bottom surface of the base, a bottom of the solidified soldering layer being no lower than the bottom surface of the base; and
a heat sink being arranged on the top surface of the base with the condensing section of the heat pipe extending therethrough.

2. The heat dissipation device as described in claim 1, wherein the distance is varied between 0.1 mm and 0.3 mm, and the bottom of the solidified soldering layer is coplanar with the bottom surface of the base.

3. The heat dissipation device as described in claim 1, wherein the evaporating section has a semi-circular cross section, and the at least one groove has a semi-circular cross section which has a diameter substantially equaling to that of the cross section of the evaporating section.

4. The heat dissipation device as described in claim 1, wherein the evaporating section is parallel to the condensing section, the at least one heat pipe further comprising an adiabatic section connected the evaporating section with the condensing section, at least one through hole being defined in the heat sink for the condensing section extending therethrough, at least one receiving slot being defined in the heat sink for receiving the adiabatic section therein.

5. The heat dissipation device as described in claim 4, wherein at least one cutout is defined in one end of base, the at least one cutout communicated with the at least one groove and the at least one receiving slot simultaneously.

6. The heat dissipation device as described in claim 5, wherein the at least one receiving slot communicates with the at least one through hole and extends to a bottom surface of the heat sink to define an opening thereat, the opening being aligned with the at least one cutout of the base.

7. The heat dissipation device as described in claim 1, wherein a difference between a maximal depth of the at least one groove and a maximal height of the evaporating section is varied between 0.1 mm and 0.3 mm.

8. A method for manufacturing a heat dissipation device comprising:
providing a base with at least one groove at a bottom surface thereof;
providing at least one heat pipe comprising an evaporating section with a cross section smaller than a cross section of the at least one groove and a condensing section, the evaporating section comprising a flat outside surface at one side thereof, inserting the evaporating section into the at least one groove with the flat outside surface exposed downwardly and spaced a distance from the bottom surface of the base;
injecting an amount of solder paste into the at least one groove to fill a remaining space that is not occupied by the evaporating section in the at least one groove, and forming a solidified soldering layer on the flat outside surface after the injected solder paste is solidified with a part of the solidified soldering layer protruding downwardly beyond the bottom surface of the base;
forming a planar surface which is no lower than the bottom surface of the base by milling the protruded part of the solidified soldering layer;
providing a heat sink arranged on a top surface the base and thermally connected to the condensing section of the at least one heat pipe.

9. The method as described in claim 8, wherein the distance is varied between 0.1 mm and 0.3 mm.

10. The method as described in claim 8, wherein the evaporating section has a semi-circular cross section, and the at least one groove has a semi-circular cross section which has a diameter substantially equaling to that of the cross section of the evaporating section.

11. The method as claimed in claim 8, wherein the planar surface formed by milling the protruded part of the solidified soldering layer is coplanar with the bottom surface of the base.
